(19) United States
(12) Patent Application Publication
(10) Pub. No.: US 2024/0421147 A1
(43) Pub. Date: Dec. 19, 2024

(54) RECESS POLY ESD DIODE FOR POWER MOSFET

(71) Applicant: Alpha and Omega Semiconductor International LP, Toronto (CA)

(72) Inventors: Sik Lui, Sunnyvale, CA (US); Jian Wang, Portland, OR (US)

(21) Appl. No.: 18/335,131

(22) Filed: Jun. 15, 2023

(51) Int. Cl. H01L 27/02; H01L 29/66

(52) U.S. Cl. CPC H01L 27/0255; H01L 29/66136

(57) ABSTRACT

A protection structure for a power transistor includes one or more pairs of back-to-back pn junction diodes formed in a trench polysilicon layer provided in trenches formed in a semiconductor substrate. At least a portion of the trench polysilicon layer protrudes above the top surface of the semiconductor substrate. Alternating N-type doped regions and P-type doped regions are formed in the trench polysilicon layer along a length of the trench. The protection structure, when coupled across the gate and source terminals of the power transistor can be advantageously applied to protect the power transistor from high voltage ESD events.

### FIELD OF THE INVENTION

The invention relates to protection circuits for power semiconductor devices and, in particular, to an electrostatic discharge protection circuit for a power transistor.

### BACKGROUND OF THE INVENTION

Voltages and current transients are major causes of integrated circuit failure in electronic systems. Transients are generated from a variety of sources both internal and external to the system. For instance, common sources of transients include normal switching operations of power supplies, AC line fluctuations, lightning surges, and electrostatic discharge (ESD). High voltage transient events can cause failure in integrated circuits by permanently damaging the materials used to form the integrated circuits.

Power transistors, such as power MOSFETs, are often used in applications for switching voltage from a few volts up to thousands of volts. Such power transistors often include a protection circuit integrated therewith for protecting the power transistor against electrostatic discharge (ESD) from handling during the system assembly process and human handling in a consumer product. For example, the gate terminal of the power transistor may not be able to withstand a high energy ESD event. On-chip ESD protection circuits typically include various diode structure coupled to protect the input gate of the power MOSFET. The ESD protection circuit provides an electrical path to divert the current induced by a high voltage ESD event away from the power MOSFET device, thereby preventing the MOSFET device from being damaged. In some examples, Trench polysilicon diode for use as ESD protection diode has been described, such as in U.S. Pat. Nos. 8,476,676 and 9,431,550.

FIG. 1 is a schematic diagram illustrating a power transistor with an ESD protection circuit in some examples. Referring to FIG. 1, a power transistor 1, or a power MOSFET, includes a gate terminal G as the control gate input, a drain terminal D, typically connected to a power supply, and a source terminal S, typically connected to a load. A diode BD denotes the body diode formed in the power MOSFET 1 and it is understood the body diode BD is a parasitic device of the transistor structure and not a separately formed diode device. The power MOSFET 1 requires ESD protection to the gate terminal G. In the present example, an ESD protection circuit 2, configured as a back-to-back diode string, is provided between the gate and source terminals of the power MOSFET device. More specifically, the ESD protection circuit 2 includes one or more pairs of back-to-back connected pn junction diodes. In the present example, the ESD protection circuit 2 includes one pair of back-to-back connected pn junction diodes formed by diodes D1 and D2. The diodes D1 and D2 are connected back-to-back in that their anodes are connected together. The cathode of diode D1 is connected to the gate terminal G of the power MOSFET while the cathode of diode D2 is connected to the source terminal. To effectuate protection against high voltage ESD events, the breakdown voltage of diodes D1 and D2 are greater than the maximum operating voltage at the gate terminal but less than the gate dielectric breakdown voltage. In this manner, power MOSFET 1 operates normally within the operating voltage range but the diode strings of D1 and D2 are activated in case of a high voltage ESD event to divert away current to protect the gate terminal of the power MOSFET from damage. Multiple pairs of back-to-back diodes are used to support higher operating gate voltage at the power MSOFET. In the case of multiple back-to-back diodes, the cathode of the first diode and the cathode of the last diode are connected to respective gate and source terminals.

FIG. 2 is a perspective view of a power transistor and an ESD protection structure formed on a semiconductor substrate in some examples. In particular, FIG. 2 illustrates a typical implementation for providing a diode string as ESD protection circuit for a trench gate power transistor. Referring to FIG. 2, a power transistor 10 is formed as a vertical transistor with the polysilicon gate terminal 14 provided in trenches formed in a semiconductor substrate 12. The polysilicon gate 14 is isolated from the semiconductor substrate 12 by a gate dielectric layer 15. A body region 16, such as a P-type doped region, is formed in a top portion of the semiconductor substrate 12. A source region 18, such as a heavily doped N-type doped region or N+ doped region, is formed in the body region 16. The semiconductor substrate 12 forms the drain terminal of the power transistor 10.

In this configuration, a ESD protection circuit 20 is constructed as back-to-back polysilicon diodes that are formed on top of the semiconductor substrate 12, in an area separate from the power transistor 10. For example, a polysilicon layer 25 is formed on the semiconductor substrate 12 and isolated from the substrate by a dielectric layer 26, such as a silicon oxide layer. The polysilicon layer 25 is masked and doped to form alternate N-type doped regions 22 and P-type doped regions 24. In most cases, the N-type regions 22 re more heavily doped than the P-type regions 24. The alternate N-type and P-type doped regions form the back-to-back pn junction diodes, as represented by diodes D1, D2, D3, etc. Metal contacts and metal interconnects are used to connect the diode string to the gate and source terminals of the power transistor 10.

As thus configured, the ESD rating of the ESD protection circuit 20 is determined by the cross-section area of the polysilicon layer 25 at the N-P doped regions interface. If increased ESD rating is desired, the planar area of the polysilicon layer 25 has to be made bigger, which requires more substrate area to implement, and therefore more costly. Also, the polysilicon layer 25 being formed above the semiconductor substrate 12 increases the step-height of the device, requiring the use of thick photoresist and thereby limiting the use of advance photolithography. It is also not ideal to increase the vertical thickness of the polysilicon layer 25 to increase the cross-section area for ESD rating as it would result in further increase in step height.

### SUMMARY OF THE INVENTION

According to one embodiment of the present invention, a protection structure for a power transistor including a gate terminal, a first current terminal and a second current terminal includes at least one pair of pn junction diodes connected in a back-to-back configuration, the pn junction diodes being provided in a first portion of a semiconductor substrate, the pn junction diodes being formed in a first polysilicon layer provided in a first trench formed in the semiconductor substrate, the first polysilicon layer being isolated from the semiconductor substrate by a first dielectric layer formed on sidewalls of the first trench, the first polysilicon layer having alternating doped regions of first and second conductivity types along a length of the first trench, at least a portion of the first polysilicon layer being formed above a first surface of the semiconductor substrate. A first doped region of the first conductivity type in the first polysilicon layer is coupled to the gate terminal of the power transistor and a second doped region of the first conductivity type in the first polysilicon layer is coupled to the second current terminal of the power transistor, the first doped region is separated from the second doped region by a third doped region of the second conductivity type.

According to another embodiment of the present invention, a method for fabricating a protection structure for a power transistor including a gate terminal, a first current terminal and a second current terminal includes forming a first plurality of trenches in a first area of a semiconductor substrate, the first plurality of trenches having a length extending in a first direction; forming a first polysilicon layer in the first plurality of trenches, the first polysilicon layer being isolated from the semiconductor substrate by a first dielectric layer; subsequent to forming the first polysilicon layer, forming a second plurality of trenches in a second area of a semiconductor substrate, the second plurality of trenches having a length extending in the first direction; forming a second dielectric layer in the second plurality of trenches and above a first surface of the semiconductor substrate in the first area; forming a second polysilicon layer in the second plurality of trenches and above the second dielectric layer, the second polysilicon layer being isolated from the semiconductor substrate by a second dielectric layer; removing portions of the second polysilicon layer and the second dielectric layer from the first area of the semiconductor substrate, remaining portions of the second polysilicon layer being formed in the second plurality of trenches and at least a part of the second polysilicon layer in each of the second plurality of trenches being formed above the first surface of the semiconductor substrate; and forming alternating doped regions of first and second conductivity type in each trench of the second plurality of trenches, the doped regions being alternately formed along the length of each respective trench in the second plurality of trenches.

These and other advantages, aspects, and novel features of the present invention, as well as details of an illustrated embodiment thereof, will be more fully understood from the following description and drawings.

### BRIEF DESCRIPTION OF THE DRAWINGS

Various embodiments of the invention are disclosed in the following detailed description and the accompanying drawings. Although the drawings depict various examples of the invention, the invention is not limited by the depicted examples. It is to be understood that, in the drawings, like reference numerals designate like structural elements. Also, it is understood that the depictions in the figures are not necessarily to scale.

FIG. 1 is a schematic diagram illustrating a power transistor with an ESD protection circuit in some examples.

FIG. 2 is a perspective view of a power transistor and an ESD protection structure formed on a semiconductor substrate in some examples.

FIG. 3 is a perspective view of a power transistor and an ESD protection structure formed in a trench polysilicon layer in embodiments of the present invention.

FIG. 4 is a perspective view of a power transistor and an ESD protection structure formed in a trench polysilicon layer in alternate embodiments of the present invention.

FIG. 5 is a cross-sectional view of the ESD protection structure of FIG. 3 along the line A-A′ in some embodiments.

FIG. 6 is a cross-sectional view of an ESD protection structure in an alternate embodiment.

FIGS. 7(a) to 7(t) are cross-sectional views illustrating a fabrication process for forming the power transistor incorporating an ESD protection structure in embodiments of the present invention.

FIG. 8 is a simplified layout view of a power transistor incorporating an ESD protection structure in embodiments of the present invention.

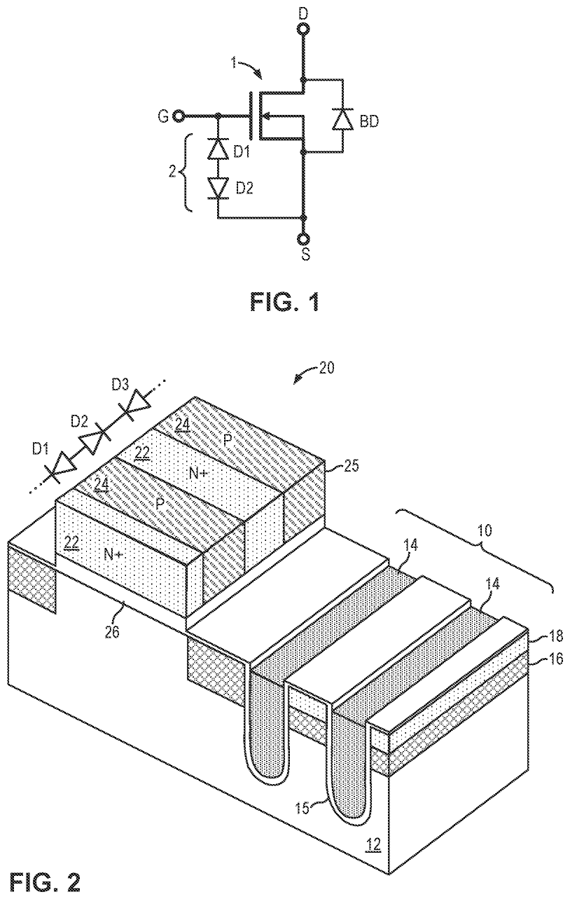

### DETAILED DESCRIPTION OF THE INVENTION

According to aspects of the present invention, a protection structure for a power transistor includes one or more pairs of back-to-back pn junction diodes formed in a trench polysilicon layer provided in trenches formed in a semiconductor substrate. At least a portion of the trench polysilicon layer protrudes above the top surface of the semiconductor substrate. Alternating N-type doped regions and P-type doped regions are formed in the trench polysilicon layer along a length of the trench. The protection structure, when coupled across the gate and source terminals of the power transistor can be advantageously applied to protect the power transistor from ESD events. In the present description, the pn junction diodes of the protection structure are sometimes referred to as ESD diodes or polysilicon ESD diodes.

The protection structure in embodiments of the present invention realizes many advantages over the conventional structures. First, by forming the ESD diodes in a trench polysilicon layer, the protection structure can be implemented without requiring large silicon real estate. In particular, the cross-section area of the pn junction interface is extended by providing a portion of the trench polysilicon layer above the semiconductor substrate surface. In this manner, only a small step height results while the cross-sectional area of the ESD diode is increased to improve the protection rating of the protection structure. Second, the fabrication process enables the trench structures for the ESD diodes to be formed after the trench structures for the power transistors with minimal topographic effects on the power transistor trench formation. This enables the ESD diode fabrication process to be decoupled from the power transistor fabrication process and enables the trench polysilicon layer of the ESD diodes to be formed protruding above the semiconductor substrate surface. These and other advantages of the protection structure and method of fabrication will be described in more detail below.

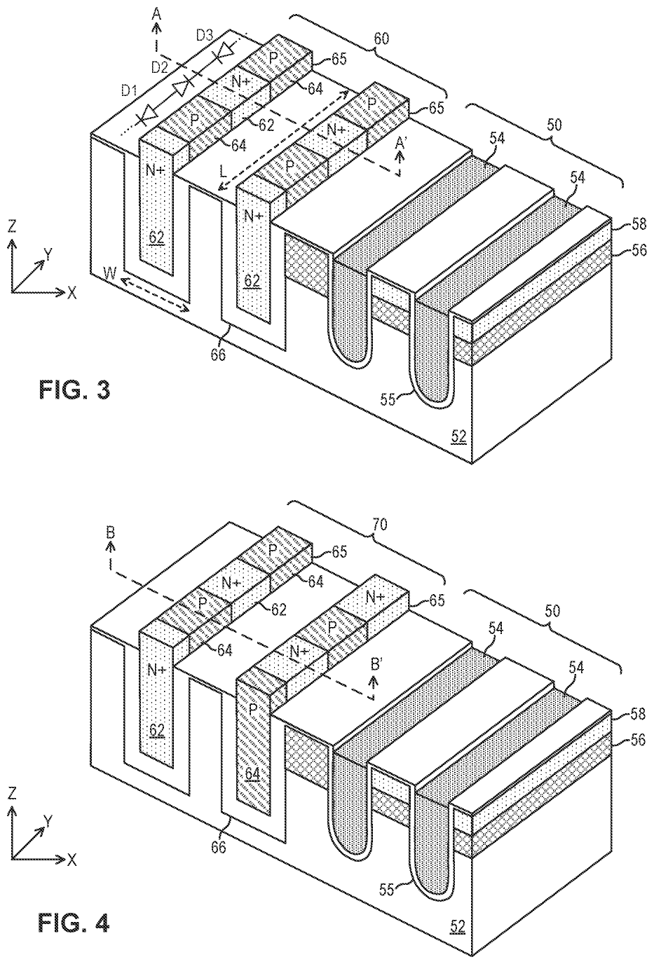

FIG. 3 is a perspective view of a power transistor and an ESD protection structure formed in a trench polysilicon layer in embodiments of the present invention. Referring to FIG. 3, a power transistor 50 (also referred to as a “power MOSFET”) is constructed as a vertical transistor with a gate polysilicon layer 54 provided in one or more trenches (referred herein as “device trenches”) forming the gate terminal. The gate polysilicon layer 54 is provided in device trenches that are formed in a device area of a semiconductor substrate 52. The gate polysilicon layer 54 is isolated from the semiconductor substrate 52 by a gate dielectric layer 55. In the present embodiment, the power transistor is an N-type field effect transistor and the semiconductor substrate 52 is a lightly doped N-type epitaxial layer formed on a heavily doped N-type substrate and serves as the drain terminal of the power transistor. Ohmic contact to the drain terminal of the power transistor may be provided from the backside of the semiconductor substrate. A body region 56 is formed in a top portion of the semiconductor substrate 52. A source region 58 is formed in the body region 56. For example, the body region 56 is a P-type doped region and the source region 58 is a heavily doped N-type doped region or N+ doped region. The body region 56 is more lightly doped than the source region 58 but more heavily doped than the semiconductor substrate 52. As thus configured, a channel region is formed on the sidewalls of the gate polysilicon layer 54 in the body region by the application of a gate voltage to the gate terminal sufficient to invert the body region adjacent the gate polysilicon layer 54. The power transistor 50 has a vertical current path between the drain (substrate 52) and the source region 58, through the inverted channel region in the body region 56.

In embodiments of the present invention, an ESD protection structure 60 is formed on the same semiconductor substrate 52 as the power transistor 50. The ESD protection structure 60 is constructed as back-to-back polysilicon diodes (referred herein as “ESD diodes”) in a trench polysilicon layer 65 provided in trenches (referred herein as “ESD trenches”) formed in an ESD area of the semiconductor substrate 52, separate from the device area where the power transistor 50 is formed. The trench polysilicon layer 65 in the ESD trenches are isolated from the semiconductor substrate 52 by a dielectric liner layer 66. In some embodiments, the dielectric liner layer 66 is a thick dielectric layer, such as a silicon oxide (SiO₂) layer. The thickness of the dielectric liner layer 66 is selected to realize the desired ESD protection rating of the ESD diode.

In the present description, to facilitate reference to the figures, a Cartesian coordinate reference frame is used, in which the Z-direction is normal to the planar surface of the semiconductor surface and the X-direction and the Y-direction are orthogonal to the Z-direction and to each other, as indicated in the figures. In general, a trench in a semiconductor substrate refers to a long and narrow channel made in the semiconductor substrate. In the present embodiment, each ESD trench has a length L that extends in a first direction (Y-direction) of the semiconductor substrate and a width W that extends in a second direction (X-direction), orthogonal to and in the same plane as the first direction, of the semiconductor substrate. The length L of the ESD trenches is much larger than the width W of the ESD trenches. In other words, the length of the ESD trenches refers to the long dimension of the trenches and the width of the ESD trenches refers to the narrow dimension of the trenches. Finally, the ESD trenches has a depth in the third direction (Z-direction). In embodiments of the present invention, the depth of the ESD trenches is greater than the depth of the device trenches forming the power transistor 50.

In embodiments of the present invention, the trench polysilicon layer 65 is formed in the ESD trenches and further includes a part of the polysilicon layer that extends above a top surface of the semiconductor substrate 52. It is instructive to note that the gate polysilicon layer 54 forming the gate terminal of the power transistor is formed entirely in the trenches and do not extend above the top surface of the semiconductor substrate 52. However, in embodiments of the present invention, the trench polysilicon layer 65 forming the ESD diodes are formed with a portion extending above the top surface of the semiconductor substrate (in the Z-direction). This construction has the effect of maximizing the cross-section area (the X-Z plane) of the ESD diodes, thereby increasing the ESD protection rating of the ESD diodes.

To form the ESD diodes, alternating N-type doped regions 62 and P-type doped regions 64 are formed in the trench polysilicon layer 65 to form the back-to-back connected pn junction diodes. In some embodiments, the N-type doped regions 62 are more heavily doped than the P-type doped regions 64. In embodiments of the present invention, the N-type doped regions and P-type doped regions are alternately formed along the length of each ESD trench, that is, along the Y-direction of the ESD trenches. Suitable numbers of N and P doped regions are used to form the desired diode string in the ESD protection structure. For example, in the present illustration, two N-type and two P-type doped regions are provided in each ESD trench, and a diode string of diodes D1, D2 and D3 are thus formed as shown. It is understood that FIG. 3 illustrates only a portion of the power transistor and the ESD protection structure. The complete ESD protection structure may include additional N/P doped regions and/or additional ESD trenches.

Although not shown in FIG. 3, it is understood that a first N-type doped region forming the cathode of the first diode in the diode string is to be connected to the gate terminal (gate polysilicon layer 54) of the power transistor, such as through contact structures and conductive interconnects. Furthermore, it is understood that a last N-type doped region forming the cathode of the last diode in the diode string is to be connected to the source terminal 58 of the power transistor, similarly through contact structures or conductive interconnects.

In the embodiments shown in FIG. 3, the ESD protection structure includes two ESD trenches, each with trench polysilicon layer 65 formed therein. It is understood that, in other embodiment, the ESD protection structure can be constructed using a single ESD trenches or multiple ESD trenches. The N/P doped regions formed in the trench polysilicon layer 65 in each ESD trench form a diode string of back-to-back connected pn junction diodes. The diode strings formed in the multiple ESD trenches may be connected to each other in series or in parallel, depending on the ESD protection voltage and other performance characteristics desired, such as the resistance of the ESD protection structure.

Furthermore, in the embodiments shown in FIG. 3, the N-type doped regions 62 and the P-type doped regions 64 in the multiple ESD trenches are horizontally aligned in the first direction (the Y-direction). That is, an N-doped region 62 in the first ESD trench is aligned to an N-doped region 62 in the adjacent ESD trench, such as along a line A-A′. The P-doped regions 64 are similarly aligned. In other embodiments, the N-type doped regions 62 and the P-type doped regions 64 may be staggered or offset in the first direction (the Y-direction), as shown in FIG. 4. FIG. 4 is a perspective view of a power transistor and an ESD protection structure formed in a trench polysilicon layer in alternate embodiments of the present invention. Like elements in FIGS. 3 and 4 are given like reference numbers to simplify the discussion. Referring to FIG. 4, an ESD protection structure 70 includes ESD diodes formed in ESD trenches in the same manner as the ESD protection structure 60 of FIG. 3. In the embodiment shown in FIG. 4, the N-type doped regions 62 and the P-type doped regions 64 in the multiple ESD trenches are horizontally staggered or offset in the first direction (the Y-direction). Thus, along a line B-B′, an N-doped region 62 in the first ESD trench is aligned to a P-doped region 64 in the adjacent ESD trench.

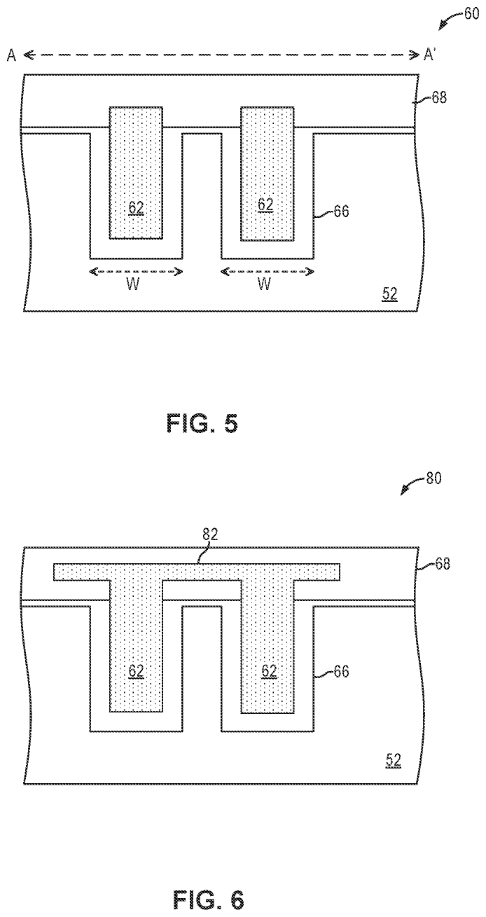

FIG. 5 is a cross-sectional view of the ESD protection structure of FIG. 3 along the line A-A′ in some embodiments. Referring to FIG. 5, along the line A-A′, the ESD protection structure includes the trench polysilicon layer with the N-type doped regions 62 of the ESD diodes formed in the two adjacent ESD trenches. The N-type doped regions 62 formed in ESD trenches are isolated from the semiconductor substrate 52 by the dielectric liner layer 66. In the cross-sectional view of FIG. 5, the ESD protection structure is capped by an inter-layer dielectric layer 68 (e.g. a LTO or BPSG layer). In the case the N-type doped regions and the P-type doped regions are formed staggered as in FIG. 4, the cross-sectional view along the line B-B′ will include the trench polysilicon layer with an N-type doped region 62 and a P-type doped region 64 formed in the two adjacent ESD trenches.

FIG. 6 is a cross-sectional view of an ESD protection structure in an alternate embodiment. Like elements in FIGS. 3 and 6 are given like reference numbers to simplify the discussion. Referring to FIG. 6, an ESD protection structure 80 is formed in substantially the same manner as the ESD protection structure 60 of FIG. 3. In the present embodiment, the trench polysilicon layer 65 in which the N/P doped regions are formed includes a polysilicon cap layer 82 which connects the trench polysilicon layer 65 across all the ESD trenches. In some embodiments The polysilicon cap layer 82 is a portion of the same trench polysilicon layer 65 which is patterned to form the cap layer portion. For example, during the intermediate processing step when a polysilicon layer is deposited into the ESD trenches, the as-deposited polysilicon layer is thinned, such as by chemical mechanical polishing, to a certain thickness to leave behind the bridging portions. The remaining polysilicon layer is then patterned and etched to form the cap layer 82. The polysilicon cap layer 82 effectively increase the cross section area of the ESD diodes.

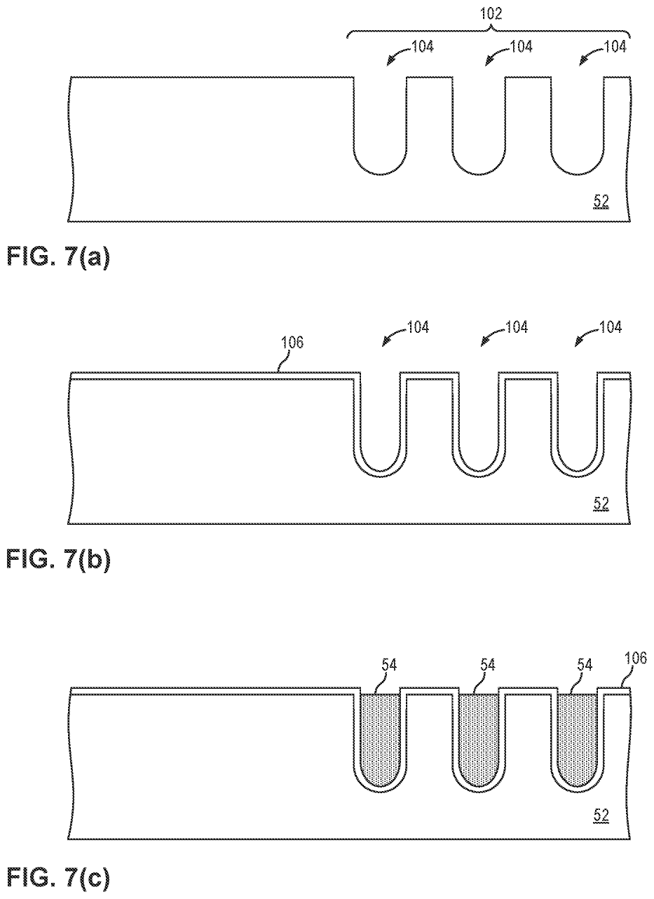

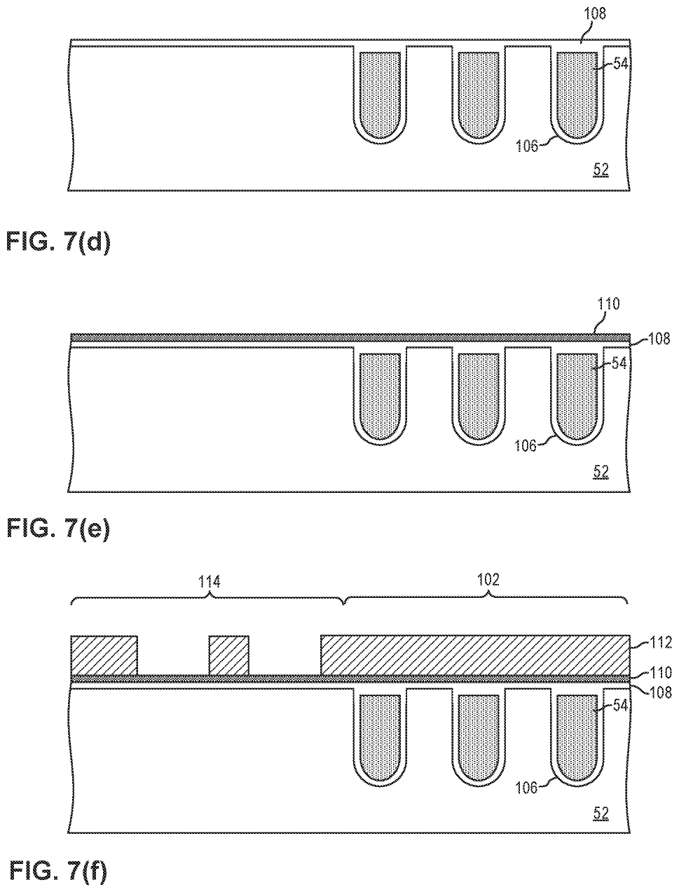

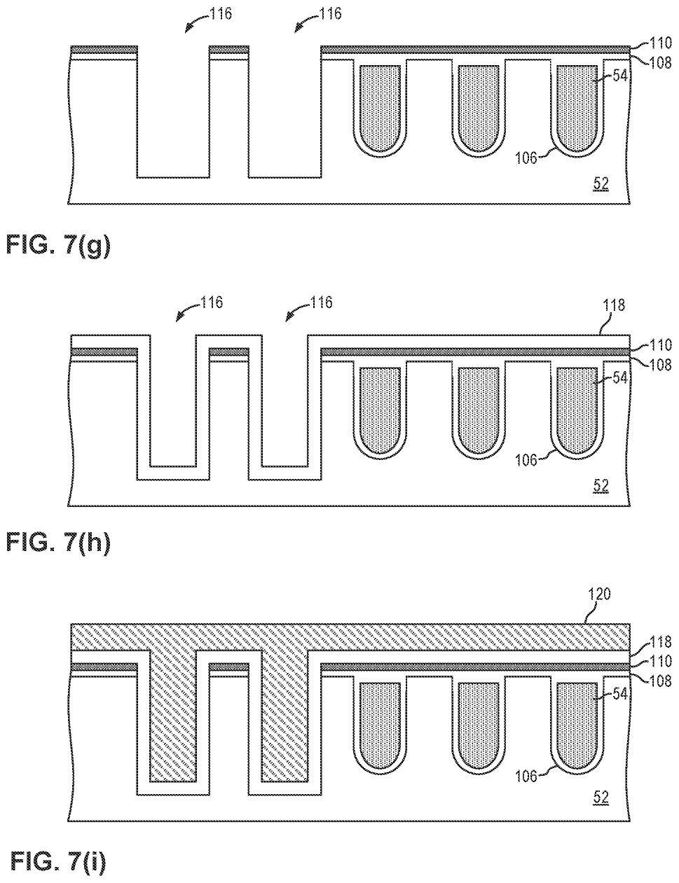

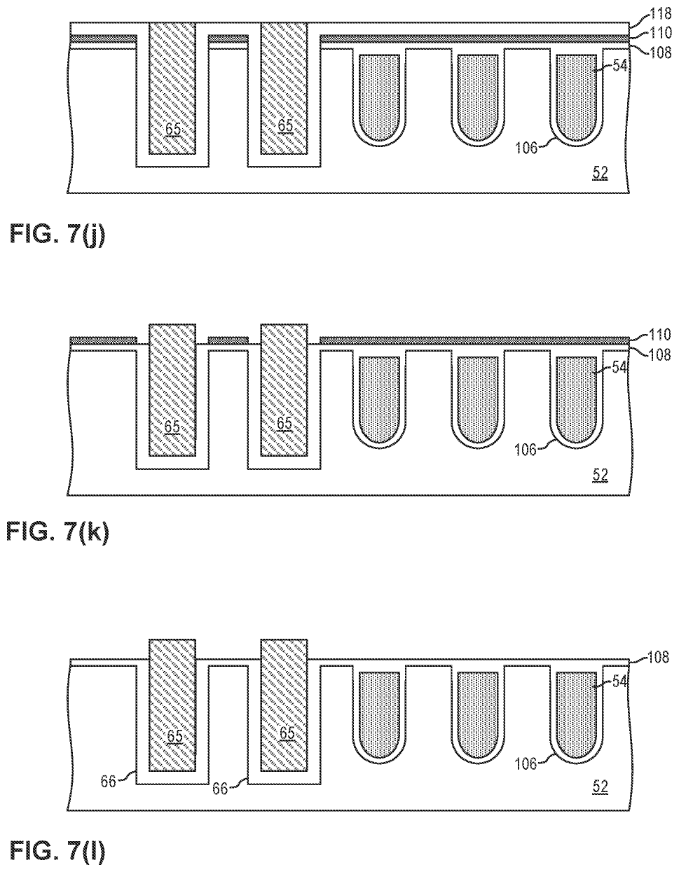

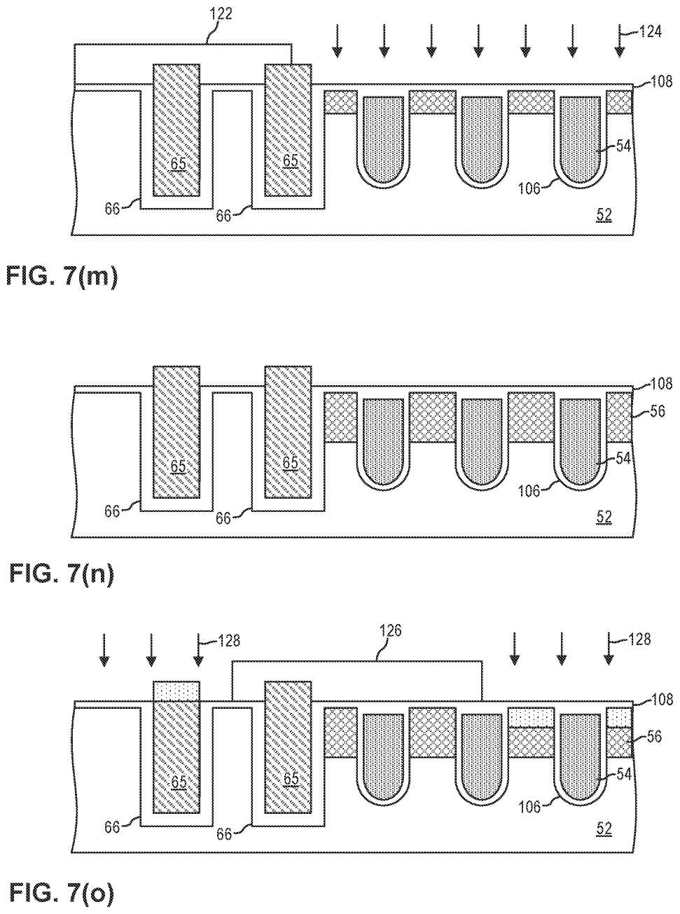

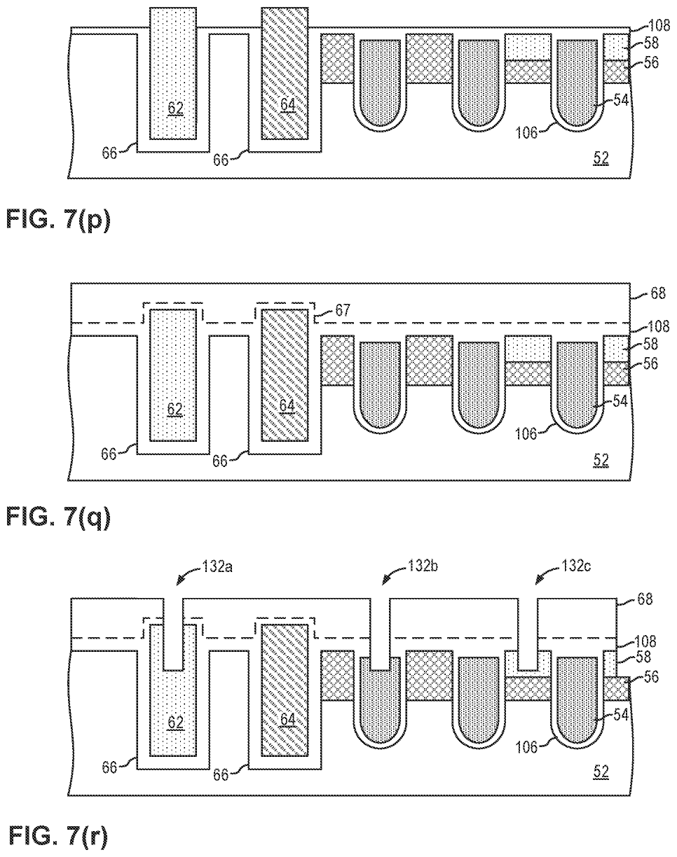

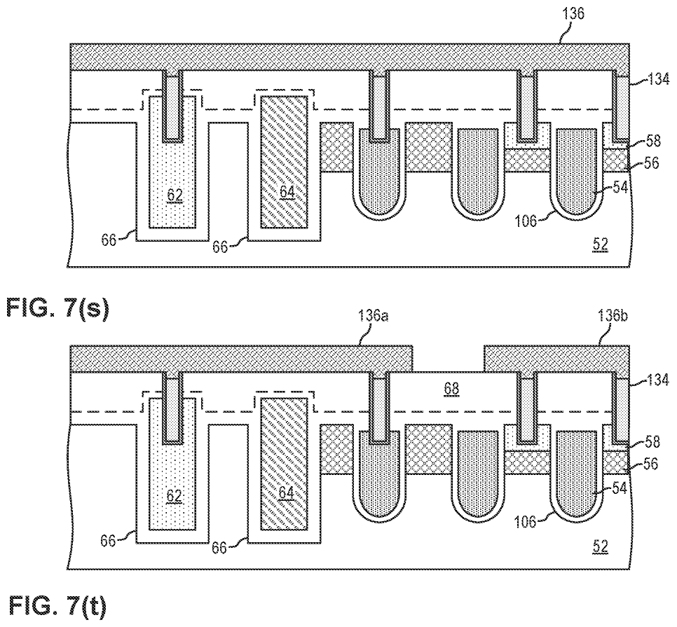

FIGS. 7(a) to 7(t) are cross-sectional views illustrating a fabrication process for forming the power transistor incorporating an ESD protection structure in embodiments of the present invention. Like elements in FIGS. 3, 4 and 7(a) to 7(t) are given like reference numbers to simplify the discussion. In particular, the fabrication process described herein forms the device trenches and the gate polysilicon layer before forming the ESD trenches and the trench polysilicon layer for the ESD diodes, which has the advantage of allowing the ESD trench polysilicon layer to be formed extended slightly above the surface of the semiconductor substrate to extend the cross-sectional area of the ESD diodes for improved ESD protection rating. The fabrication process also minimizes the topography to enable the use of thin photoresist for advance lithography for the subsequent layers.

Referring to FIG. 7(a), the fabrication process starts with forming the device trenches 104 in a device area 102 of a semiconductor substrate 52. The device trenches 104 may be formed by applying a mask to define areas for forming the trenches and then performing an anisotropic dry etch process. Referring to FIG. 7(b), subsequent to the device trench formation, a gate dielectric layer 106 is formed on the surface of the semiconductor substrate 52, by either a chemical vapor deposition (CVD) process or thermally grown. In one embodiment, the gate dielectric layer 106 is a silicon dioxide layer (SiO₂) and the gate dielectric layer 106 is also referred to as a gate oxide layer. Referring to FIG. 7(c), a gate polysilicon layer 54 formed in the device trenches 104. In some embodiments, a doped polysilicon layer is conformally deposited over the semiconductor substrate and the as-deposited doped polysilicon layer is etched back so that only the polysilicon layer in the device trenches 104 remains, forming the gate polysilicon layer 54. In some examples, the polysilicon layer can be deposited using a CVD process and etched back using a wet etch or a dry etch process.

Referring to FIG. 7(d), the gate polysilicon layer 54 is oxidized to form a cap oxide portion 108 on the polysilicon layer in each trench. For example, the gate polysilicon oxidation can be performed using a dry or wet oxidation process. In practice, the cap oxide portions 108 merges with the gate oxide layer previously deposited to form a continuous oxide layer. After the oxidation process, the surface of the semiconductor substrate 52 is substantially planarized. In the present description, for ease of reference, the portions of the oxide layer formed inside the device trenches are referred to as the gate dielectric layer or gate oxide layer 106 and the portions of the oxide layer formed on top of the gate polysilicon layer and the top of the semiconductor substrate are referred to as the cap oxide layer 108. Referring to FIG. 7(e), a silicon nitride layer 110 is deposited onto the semiconductor substrate 52, for example, using a CVD process. At this stage, the fabrication process has completed the trench gate structure formation for the power transistor. The fabrication process now proceeds to form the ESD trench structures for the ESD protection structure.

Referring to FIG. 7(f), an ESD mask 112 is applied which covers and protects the structures formed in the device area 102 and exposes areas in the ESD area 114 in which ESD trenches are to be formed. Referring to FIG. 7(g), with the mask 112 thus applied, the silicon nitride layer 110 and the cap oxide layer 108 in the exposed areas are etched. The fabrication process then forms ESD trenches 116 in the areas exposed by the mask 112. For example, the silicon nitride layer 110 and the cap oxide layer 108 may be etched using a dry etch process using the applicable etch chemistry. The ESD trenches 116 may be formed by performing an anisotropic dry etch process. In embodiments of the present invention, the ESD trenches 116 has a depth deeper than the depth of the device trenches. Furthermore, the ESD trenches 116 has a width wider than the width of the device trenches.

In the present embodiment, the device trenches are shown as having a rounded bottom whereas the ESD trenches 116 are shown as having a square bottom. It is understood that the exact shapes of the device and ESD trenches are a function of the etch process and rounded or flat corners may be achieved by using different etch conditions. In general, because the device trenches are smaller, the trenches generally have a rounded bottom. Furthermore, a rounded bottom is typically targeted for the gate polysilicon layer to reduce the concentration of electric field that may occur at sharp corners. On the other hand, the ESD trenches are wider and deeper than the device trenches and the etch conditions may favor a more opened trench bottom. It is understood that the profile of the ESD trenches does not have to be a perfect rectangular trench bottom and the figures provided herein are illustrative only.

After the ESD trench formation, any mask or photoresist layer is removed. Referring to FIG. 7(h), a dielectric liner layer 118 is deposited on the semiconductor substrate 52. In one example, the dielectric liner layer 118 is a TEOS oxide layer and is deposited using a CVD process. Referring to FIG. 7(i), a polysilicon layer 120 is deposited on the semiconductor substrate 52, such as using a CVD process. In the present embodiment, the polysilicon layer 120 is referred to as an ESD polysilicon layer. In the present embodiment, the ESD polysilicon layer 120 is deposited undoped or very lightly doped. After deposition, an ESD implant is applied to dope the ESD polysilicon layer 120. In the present embodiment, the ESD implant introduces P-type dopants to the ESD polysilicon layer 120. The amount of ESD implant is selected to tune the characteristics of the ESD polysilicon layer.

Referring to FIG. 7(j), the ESD polysilicon layer 120 is etched back, such as by using a chemical mechanical polishing (CMP) process. In the present embodiment, the CMP process continues to the top of the dielectric liner layer 118, such as by using the dielectric liner layer 118 as an etch stop. As a result, trench polysilicon layer 65 is formed in the ESD trenches. Furthermore, the trench polysilicon layer 65 has a height that would extends above semiconductor substrate.

In the case a polysilicon cap layer (FIG. 6) is to be formed bridging the trench polysilicon portions, the CMP process is performed to etch back only a portion of the ESD polysilicon layer 120 from the top. The thinned ESD polysilicon layer 120 is then patterned and etched to form the polysilicon cap layer, as shown in FIG. 6.

Referring now to FIG. 7(k), the dielectric liner layer 118 is etched back from the top, such as by using a dry etch process utilizing the silicon nitride layer 110 as the etch stop layer. Then, referring to FIG. 7(l), the silicon nitride layer 118 is removed, such as by using a dry etch process. At this stage, the trench polysilicon layer 65 is formed with part of the polysilicon layer protruding from the top surface of the semiconductor substrate 52. The amount that protrudes is a function of the dielectric liner layer and the silicon nitride layer that are now removed. Portions of the dielectric liner layer remaining in the ESD trenches form the dielectric liner layer 66 for isolating the trench polysilicon layer 65 from the semiconductor substrate 52.

At this stage, an anneal process for the gate polysilicon layer 54 and the trench polysilicon layer 65 can be performed. The anneal process may be performed in a non-reactive ambient at a high temperature, for example. Referring to FIG. 7(m), after the polysilicon anneal, a body mask 122 is applied which exposes areas for receiving the body implant 124. In the present embodiment, the body implant is applied only to the device area. For example, the body implant 124 may be a lightly doped P-type implant. Referring to FIG. 7(n), a body anneal process for the body implant is performed to anneal and diffuse the implanted dopants, forming the body region 56. The anneal process may be performed in a non-reactive ambient at a high temperature, for example.

Referring to FIG. 7(o), after the body anneal process, a source mask 126 is applied which exposes areas for receiving the source implant 128. For example, the source implant 128 may be a heavily doped N-type implant. In the present embodiment, the source implant is applied to both the device area and the ESD area. Referring to FIG. 7(p), a source anneal process for the source implant is performed to anneal and diffuse the implanted dopants, forming the source region 58 in the power transistor and forming the N-type doped region 62 in the ESD diode. The anneal process may be performed in a non-reactive ambient at a high temperature, for example. Note that FIG. 7(p) illustrates the embodiment of the ESD diodes in FIG. 4 where the N and P doped regions are staggered. Therefore, in the cross-sectional view in FIG. 7(p), the trench polysilicon layer in the leftmost ESD trench is shown as being an N-type doped region 62 while the trench polysilicon layer in the rightmost ESD trench is shown as being a P-type doped region 64.

Referring to FIG. 7(q), after the source anneal process, the power transistor and the ESD diodes thus formed are encapsulated by an inter-layer dielectric layer. In the present embodiment, a low-temperature oxide layer (LTO) 67 is deposited followed by the deposition of a borophosphosilicate glass (BPSG) layer 68. The layers can be deposited using CVD processes, for example. After the BPSG deposition, the semiconductor structure can be planarized.

Referring to FIG. 7(r), a contact mask is applied to define openings to be made in the inter-layer dielectric layer. A contact etch process, such as an anisotropic dry etch process, is then carried out using the contact mask to form openings 132 to terminals of the ESD diode and the power transistor. For example, a first contact opening 132a is made to the N-type doped region 62 of the ESD diode, a second contact opening 132b is made to the gate polysilicon layer 54, and a third contact opening 132c is made to the source region 58.

Referring to FIG. 7(s), tungsten plugs 134 are formed in the contact openings 132. For example, the tungsten plugs 134 may include a conductive adhesion layer, such as a titanium (Ti) or a titanium nitride (TiN) layer, and then a tungsten filler layer, both deposited by CVD or PVD processes. A conductive layer 136 is then deposited on the semiconductor structure. In one embodiment, the conductive layer 136 is an aluminum layer and may be deposited using a PVD process or evaporation. Referring to FIG. 7(t), a metal mask is applied and the conductive layer 136 is etched using the metal mask to form metal interconnects. For example, in the present illustration, a first metal line 136a connects the N-doped region 62 of the ESD diode to the gate polysilicon layer 54 and a second metal line 136b connects to the source region 58 of the power transistor and also to be connected to another N-doped region of the ESD diode. At this stage, the fabrication process for forming the power transistor and the ESD protection structure is completed.

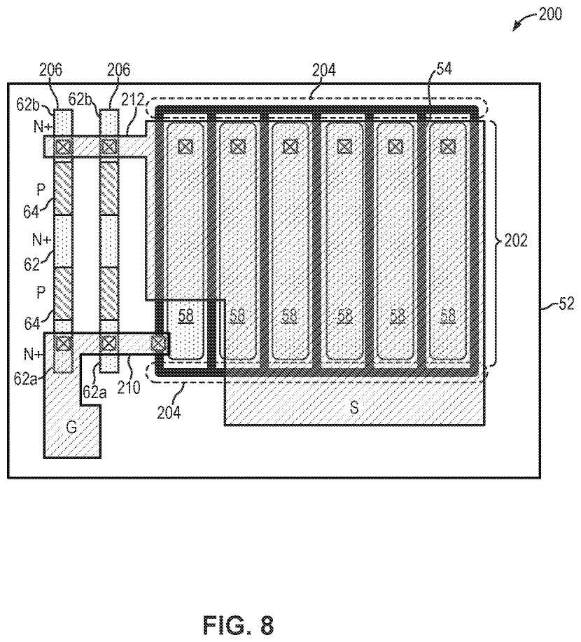

FIG. 8 is a simplified layout view of a power transistor incorporating an ESD protection structure in embodiments of the present invention. Referring to FIG. 8, a power transistor device 200 includes gate polysilicon layer 54 formed in parallel device trenches 202 in a device area of the semiconductor substrate 52. The gate polysilicon layers 54 in the parallel device trenches 202 are connected together by end polysilicon portions formed in trenches 204. The ESD protection structure is formed in ESD trenches 206 formed in an ESD area of the semiconductor substrate. For instance, the ESD protection structure includes alternating N and P doped regions 62, 64 formed in the ESD trenches 206. The ESD protection structure is connected to the power transistor by connecting an N-doped region 62a of the first ESD diode to the gate polysilicon layer, such as through contacts and an interconnect 210, and by connecting an N-doped region 62b of the last ESD diode to the source region 58 of the power transistor. In the power transistor device 200, the gate terminal is provided in a gate pad and the source terminal is provided in a source pad on a topside of the device while the drain terminal is provided on the backside of the device. In the present embodiment, the diode strings in the two ESD trenches 206 are connected in parallel. The interconnect 210 connects to the N-doped regions 62a on both diode strings and the interconnect 212 connects to the N-doped region 62b on both diode strings. As thus configured, the ESD protection structure is connected to protect the gate terminal of the power transistor 200.

The drawings provided herein are idealized representations to illustrate embodiments of the present disclosure and are not meant to be actual views of any particular component, structure, or device. The drawings are not to scale, and the sizes and relative sizes and dimensions of layers and regions may be exaggerated for clarity. Variations from the shapes of the illustrations are to be expected. For example, a region illustrated as a box shape may typically have rough and/or nonlinear features. Sharp angles that are illustrated may be rounded. Like numerals refer to like components throughout.

In the present description, spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present.

In this detailed description, process steps described for one embodiment may be used in a different embodiment, even if the process steps are not expressly described in the different embodiment. When reference is made herein to a method including two or more defined steps, the defined steps can be carried out in any order or simultaneously, except where the context dictates or specific instruction otherwise are provided herein. Further, unless the context dictates or express instructions otherwise are provided, the method can also include one or more other steps carried out before any of the defined steps, between two of the defined steps, or after all the defined steps.

In this detailed description, various embodiments or examples of the present invention may be implemented in numerous ways, including as a process; an apparatus; a system; and a composition of matter. A detailed description of one or more embodiments of the invention is provided above along with accompanying figures that illustrate the principles of the invention. The invention is described in connection with such embodiments, but the invention is not limited to any embodiment. Numerous modifications and variations within the scope of the present invention are possible. The scope of the invention is limited only by the claims and the invention encompasses numerous alternatives, modifications, and equivalents. Numerous specific details are set forth in the description in order to provide a thorough understanding of the invention. These details are provided for the purpose of example and the invention may be practiced according to the claims without some or all of these specific details. For the purpose of clarity, technical material that is known in the technical fields related to the invention has not been described in detail so that the invention is not unnecessarily obscured. The present invention is defined by the appended claims.

1. A protection structure for a power transistor, the power transistor including a gate terminal, a first current terminal and a second current terminal, the protection structure comprising:
at least one pair of pn junction diodes connected in a back-to-back configuration, the pn junction diodes being provided in a first portion of a semiconductor substrate, the pn junction diodes being formed in a first polysilicon layer provided in a first trench formed in the semiconductor substrate, the first polysilicon layer being isolated from the semiconductor substrate by a first dielectric layer formed on sidewalls of the first trench, the first polysilicon layer having alternating doped regions of first and second conductivity types along a length of the first trench, at least a portion of the first polysilicon layer being formed above a first surface of the semiconductor substrate,
wherein a first doped region of the first conductivity type in the first polysilicon layer is coupled to the gate terminal of the power transistor and a second doped region of the first conductivity type in the first polysilicon layer is coupled to the second current terminal of the power transistor, the first doped region is separated from the second doped region by at least a third doped region of the second conductivity type.

2. The protection structure of claim 1, wherein the length of the first trench extends in a first direction in the semiconductor substrate and a width of the first trench extends in a second direction, the second direction being orthogonal to the first direction and in the same plane as the first surface of the semiconductor substrate, the length of the first trench being larger than the width.

3. The protection structure of claim 1, wherein the power transistor is provided in a second portion of the semiconductor substrate, the power transistor comprises:
a second polysilicon layer formed in a second trench formed in the semiconductor substrate, the second polysilicon layer being isolated from the semiconductor substrate by a second dielectric layer;
a body region of the second conductivity type formed in and at the first surface of the semiconductor substrate adjacent the second trench; and
a source region of the first conductivity type formed in the body region adjacent the second trench,
wherein a length of the second trench is parallel to the length of the first trench.

4. The protection structure of claim 3, wherein the first trench has a depth extending into the semiconductor substrate opposite from the first surface greater than a depth of the second trench.

5. The protection structure of claim 3, wherein the first dielectric layer has a thickness greater than a thickness of the second dielectric layer.

6. The protection structure of claim 3, wherein a thickness of the first dielectric layer is selected to provide a predetermined protection voltage of the protection structure.

7. The protection structure of claim 3, wherein the semiconductor substrate forms the first current terminal of the power transistor and the source region forms the second current terminal of the power transistor, one of the first and second current terminals being coupled to a first power supply voltage and the other one of the first and second current terminals being configured to drive a load, and the second polysilicon layer forms the gate terminal which is configured to receive a control signal.

8. The protection structure of claim 1, further comprising a plurality of pairs of pn junction diodes, each pair of pn junction diodes being connected in a back-to-back configuration, the plurality of pairs of pn junction diodes being formed in the first polysilicon layer in the first trench as alternating doped regions of the first and second conductivity types along the length of the first trench.

9. The protection structure of claim 1, further comprising a plurality of pairs of pn junction diodes, each pair of pn junction diodes being connected in a back-to-back configuration, the plurality of pairs of pn junction diodes being formed in a plurality of polysilicon layers provided in a plurality of trenches in the semiconductor substrate, a subset of the plurality of pn junction diodes being formed in a given polysilicon layer in the respective trench as alternating doped regions of the first and second conductivity types along the length of the first trench, at least a portion of each of the plurality of polysilicon layers being formed above the first surface of the semiconductor substrate.

10. The protection structure of claim 9, wherein the length of the plurality of trenches extends in a first direction in the semiconductor substrate and a width of each trench extends in a second direction, the second direction being orthogonal to the first direction and in the same plane as the first surface of the semiconductor substrate, the length of the trenches being larger than the width.

11. The protection structure of claim 10, wherein the alternating doped regions of the first and second conductivity types in a first one of the plurality of trenches are aligned in the first direction as the alternating doped regions of the first and second conductivity types in a second one of the plurality of trenches.

12. The protection structure of claim 10, wherein the alternating doped regions of the first and second conductivity types in a first one of the plurality of trenches are offset in the first direction as the alternating doped regions of the first and second conductivity types in a second one of the plurality of trenches.

13. The protection structure of claim 9, wherein the plurality of the polysilicon layers of the pn junction diodes are connected together by a polysilicon cap layer formed above the plurality of polysilicon layers above the first surface of the semiconductor substrate.

14. A method for fabricating a protection structure for a power transistor, the power transistor including a gate terminal, a first current terminal and a second current terminal, the method comprising:
forming a first plurality of trenches in a first area of a semiconductor substrate, the first plurality of trenches having a length extending in a first direction;
forming a first polysilicon layer in the first plurality of trenches, the first polysilicon layer being isolated from the semiconductor substrate by a first dielectric layer;
subsequent to forming the first polysilicon layer, forming a second plurality of trenches in a second area of a semiconductor substrate, the second plurality of trenches having a length extending in the first direction;
forming a second dielectric layer in the second plurality of trenches and above a first surface of the semiconductor substrate in the first area;
forming a second polysilicon layer in the second plurality of trenches and above the second dielectric layer, the second polysilicon layer being isolated from the semiconductor substrate by a second dielectric layer;
removing portions of the second polysilicon layer and the second dielectric layer from the first area of the semiconductor substrate, remaining portions of the second polysilicon layer being formed in the second plurality of trenches and at least a part of the second polysilicon layer in each of the second plurality of trenches being formed above the first surface of the semiconductor substrate; and
forming alternating doped regions of first and second conductivity type in each trench of the second plurality of trenches, the doped regions being alternately formed along the length of each respective trench in the second plurality of trenches.

15. The method of claim 14, wherein forming the alternating doped regions of the first and second conductivity type in each trench of the second plurality of trenches comprises:
subsequent to forming the second polysilicon layer, doping the second polysilicon layer using dopants of the first conductivity type;
using a mask, patterning a mask layer to cover portions of the second polysilicon layer;
using the mask layer, doping exposed portions of the second polysilicon layer using dopants of the second conductivity type; and
annealing the semiconductor substrate to form the alternating doped regions.

16. The method of claim 14, wherein forming the second plurality of trenches comprises forming the second plurality of trenches having a depth extending into the semiconductor substrate opposite from the first surface greater than a depth of the first plurality of trenches.

17. The method of claim 14, wherein the second dielectric layer has a thickness greater than a thickness of the first dielectric layer.

18. The method of claim 15, wherein forming the alternating doped regions of the first and second conductivity type in each trench of the second plurality of trenches comprises:
forming alternating doped regions of the first and second conductivity types in a first one of the second plurality of trenches that are aligned in the first direction as the alternating doped regions of the first and second conductivity types in a second one of the second plurality of trenches.

19. The method of claim 15, wherein forming the alternating doped regions of the first and second conductivity type in each trench of the second plurality of trenches comprises:
forming alternating doped regions of the first and second conductivity types in a first one of the second plurality of trenches that are offset in the first direction as the alternating doped regions of the first and second conductivity types in a second one of the second plurality of trenches.

20. The method of claim 14, further comprises:
removing by thinning the second polysilicon layer formed over the first area and the second area of the semiconductor substrate; and
remove portions of the remaining second polysilicon layer over the first area of the semiconductor substrate, remaining portions of the second polysilicon layer including portions connecting the second polysilicon layer formed in the second plurality of trenches.
